(19) United States
(12) Patent Application Publication
(10) Pub. No.: US 2024/0147765 A1
(43) Pub. Date: May 2, 2024

(54) DISPLAY SUBSTRATE AND METHOD OF MANUFACTURING THE SAME, AND DISPLAY DEVICE

(71) Applicant: BOE Technology Group Co., Ltd., Beijing (CN)

(72) Inventor: Dejiang Zhao, Beijing (CN)

(21) Appl. No.: 18/245,923

(22) PCT Filed: Apr. 28, 2022
(86) PCT No.: PCT/CN2022/089788

§ 371 Date: Mar. 20, 2023

(51) Int. Cl. H10K 59/122; H10K 59/12

(52) U.S. Cl. CPC H10K 59/122; H10K 59/1201

(57) ABSTRACT

A display substrate, including: a base substrate; a pixel defining layer including: a plurality of first blocking portions spaced in a second direction, a plurality of second blocking portions spaced in a first direction and a plurality of barriers spaced in the first direction, each first blocking portion is parallel to the first direction, each second blocking portion is parallel to the second direction, the plurality of first blocking portions and second blocking portions surround to form a plurality of pixel light-emitting regions, and at least one barrier is disposed between adjacent second blocking portions in the second direction; a plurality of accommodating regions, at least one thereof is located between adjacent first blocking portions in the second direction and between adjacent second blocking portion and barrier in the first direction; and a first diversion structure disposed on a side of the second blocking portion away from the base substrate.

### CROSS REFERENCE TO RELATED APPLICATION

This application is a Section 371 National Stage Application of International Application No. PCT/CN2022/089788, filed on Apr. 28, 2022, entitled “DISPLAY SUBSTRATE AND METHOD OF MANUFACTURING THE SAME, AND DISPLAY DEVICE”, the whole disclosure of which is incorporated herein by reference in its entirety.

### TECHNICAL FIELD

The present disclosure relates to a field of display technology, and in particular, to a display substrate, a method of manufacturing a display substrate, and a display device.

### BACKGROUND

Compared with a traditional LCD display, an OLED (Organic Light-Emitting Display) has obvious advantages, the OLED is lighter and thinner, it has a larger viewing angle, significantly saves power consumption and materials, and is easy for mass production, etc. In a process of manufacturing a light-emitting layer in the OLED, the light-emitting layer of an OLED device is manufactured by an ink-jet printing, which may effectively improve a utilization rate of a light-emitting material, and may be patterned without using a mask. At the same time, the manufacturing process is simple and requires a low cost. However, in a process of manufacturing a light-emitting layer of a current OLED device, an inconsistent film thickness accuracy of the light-emitting layer may easily occur, resulting in a difference between a film thickness of a pixel center and a film thickness of a pixel edge, so that a difference in a display color may be generated, and a display effect and a service life of the OLED device may be affected.

It should be noted that the information disclosed in the above-mentioned background section is only used to strengthen an understanding of the background of the present disclosure, and thus information that does not constitute the prior art known to those skilled in the art may be included.

### SUMMARY

In an aspect, a display substrate is provided, comprising: a base substrate; and a pixel defining layer configured to define a plurality of pixel printing regions on the base substrate, wherein the pixel printing region is configured to be filled with a pixel printing medium, the plurality of pixel printing regions are arranged in an array in a first direction and a second direction, and the first direction forms an included angle with the second direction; wherein the pixel defining layer comprises: a plurality of first blocking portions spaced in the second direction, wherein each first blocking portion is parallel to the first direction; a plurality of second blocking portions spaced in the first direction, wherein each second blocking portion is parallel to the second direction, and the plurality of first blocking portions and the plurality of second blocking portions surround to form a plurality of pixel light-emitting regions; and a plurality of barriers spaced in the first direction, wherein at least one barrier is disposed between adjacent second blocking portions, and each barrier is parallel to the second direction; wherein the display substrate further comprises a plurality of accommodating regions disposed on the base substrate, at least one accommodating region is located between adjacent first blocking portions in the second direction and between adjacent second blocking portion and barrier in the first direction; and wherein the display substrate further comprises a first diversion structure disposed on a side of the second blocking portion away from the base substrate, and the first diversion structure is configured to divert a part of the pixel printing medium filled in the pixel light-emitting region to the accommodating region adjacent to the pixel light-emitting region.

In some exemplary embodiments of the present disclosure, the first diversion structure comprises a plurality of first diversion trenches spaced on a side of the second blocking portion away from the base substrate, an end of each first diversion trench is connected to the pixel light-emitting region, and the other end of each first diversion trench is connected to the accommodating region.

In some exemplary embodiments of the present disclosure, the second blocking portion comprises a plurality of thickened portions that are spaced apart from each other and a plurality of thinned portions that are spaced apart from each other, a thickness of each thickened portion in a third direction is greater than a thickness of each thinned portion, and the third direction is perpendicular to a plane formed by intersecting the first direction with the second direction.

In some exemplary embodiments of the present disclosure, opposite sides of two adjacent thickened portions form sidewalls of the first diversion trench, and a top surface of the thinned portion away from the base substrate forms a bottom wall of the first diversion trench.

In some exemplary embodiments of the present disclosure, the display substrate further comprises a liquid level adjusting structure disposed on at least one of the first blocking portion and the second blocking portion, and the liquid level adjusting structure is configured to: adjust the pixel printing medium in the pixel light-emitting region, so that the pixel printing medium in the pixel light-emitting region forms a flat liquid level.

In some exemplary embodiments of the present disclosure, the liquid level adjusting structure comprises a first liquid level adjusting structure disposed on the first blocking portion, and the first liquid level adjusting structure comprises: a plurality of recessed portions spaced on a side surface of the first blocking portion facing the pixel light-emitting region.

In some exemplary embodiments of the present disclosure, the recessed portion comprises a recessed portion opening and a recessed portion bottom surface, the recessed portion opening is disposed on a side surface of the first blocking portion away from the base substrate, and the recessed portion opening faces the second direction and the third direction; and wherein the recessed portion bottom surface is disposed between the side surface of the first blocking portion away from the base substrate and a side surface of the first blocking portion close to the base substrate, and the recessed portion bottom surface is located in a same plane as an upper surface of the second blocking portion away from the base substrate.

In some exemplary embodiments of the present disclosure, the liquid level adjusting structure comprises a second liquid level adjusting structure disposed on the second blocking portion, and the second liquid level adjusting structure comprises: a cylindrical structure disposed on a side of the second blocking portion away from the base substrate and extending in the third direction; and wherein the cylindrical structure is disposed on an upper surface of at least one thickened portion away from the base substrate.

In some exemplary embodiments of the present disclosure, the display substrate further comprises a second diversion structure disposed on a side surface of the first blocking portion facing the pixel light-emitting region, and the second diversion structure is configured to: divert a part of the pixel printing medium filled in the pixel light-emitting region to the accommodating region.

In some exemplary embodiments of the present disclosure, the second diversion structure comprises: a second diversion trench disposed at the first blocking portion in the first direction, and each end of the second diversion trench is respectively connected to the accommodating regions adjacent to the pixel light-emitting region.

In some exemplary embodiments of the present disclosure, the first blocking portion comprises: a first blocking sub-portion close to the pixel light-emitting region; a second blocking sub-portion away from the pixel light-emitting region; and a third blocking sub-portion located between the first blocking sub-portion and the second blocking sub-portion; and wherein in the third direction, a thickness of the second blocking sub-portion is greater than a thickness of the first blocking sub-portion, and the thickness of the first blocking sub-portion is greater than a thickness of the third blocking sub-portion.

In some exemplary embodiments of the present disclosure, the first blocking portion and the second blocking portion respectively form two sidewalls of the second diversion trench, and the third blocking portion forms a bottom wall of the second diversion trench.

In some exemplary embodiments of the present disclosure, an upper surface of the first blocking portion in the third direction is located in a same plane as an upper surface of the second blocking portion in the third direction; and wherein the bottom wall of the second diversion trench is located in a same plane as the bottom wall of the first diversion trench.

In some exemplary embodiments of the present disclosure, the display substrate further comprises an anode material layer, the anode material layer is disposed between the base substrate and the pixel defining layer, and an orthographic projection of at least one of the first blocking portion and the second blocking portion on the base substrate forms an overlapping region with an orthographic projection of the anode material layer on the base substrate.

In some exemplary embodiments of the present disclosure, at least part of an orthographic projection of the liquid level adjusting structure on the base substrate is located in the overlapping region; and/or at least part of an orthographic projection of the second diversion trench on the base substrate is located in the overlapping region; and wherein orthographic projections of the plurality of barriers on the base substrate do not overlap with the orthographic projection of the anode material layer on the base substrate.

In some exemplary embodiments of the present disclosure, a side of the first blocking portion facing the pixel light-emitting region forms an included angle with a plane formed by intersecting the first direction with the second direction, and the included angle is less than or equal to 90 degrees.

In some exemplary embodiments of the present disclosure, in the third direction, a height of the first blocking portion is greater than a height of the barrier, and the height of the barrier is greater than a height of the second blocking portion.

In another aspect, a method of manufacturing a display substrate is provided, comprising: forming a pixel defining layer on a base substrate, wherein the pixel defining layer is configured to define a plurality of pixel printing regions on the base substrate, the pixel printing region is configured to be filled with a pixel printing medium, the plurality of pixel printing regions are arranged in an array in a first direction and a second direction, and the first direction forms an included angle with the second direction; wherein the forming a pixel defining layer comprises: forming a plurality of first blocking portions spaced in the second direction, wherein each first blocking portion is parallel to the first direction; forming a plurality of second blocking portions spaced in the first direction, wherein each second blocking portion is parallel to the second direction, and the plurality of first blocking portions and the plurality of second blocking portions surround to form a plurality of pixel light-emitting regions; and forming a plurality of barriers spaced in the first direction, wherein at least one barrier is disposed between adjacent second blocking portions, and each barrier is parallel to the second direction; wherein the method further comprises forming a plurality of accommodating regions disposed on the base substrate, at least one accommodating region is located between adjacent first blocking portions in the second direction and between adjacent second blocking portion and barrier in the first direction; and wherein the method further comprises forming a first diversion structure disposed on a side of the second blocking portion away from the base substrate, and the first diversion structure is configured to divert a part of the pixel printing medium filled in the pixel light-emitting region to the accommodating region adjacent to the pixel light-emitting region.

In another aspect of the present disclosure, a display device is provided, comprising: the display substrate as described above.

### BRIEF DESCRIPTION OF THE DRAWINGS

In order to clearly describe the technical solutions of the present disclosure, accompanying drawings required in some embodiments of the present disclosure will be briefly introduced below. Obviously, the accompanying drawings in the following descriptions are only accompanying drawings of some embodiments of the present disclosure. For those skilled in the art, other accompanying drawings may also be obtained from these accompanying drawings. In addition, the accompanying drawings in the following descriptions may be regarded as schematic diagrams, and are not intended to limit an actual size of a product, an actual flow of a method, an actual timing of a signal, etc. involved in embodiments of the present disclosure.

FIG. 1 is a schematic plan view of a display substrate according to an exemplary embodiment of the present disclosure;

FIG. 2 is a partial enlarged view of an M region of the display substrate shown in FIG. 1;

FIG. 3A is schematic diagram of a plan structure of a pixel defining layer of a display substrate according to an exemplary embodiment of the present disclosure;

FIG. 3B is a cross-sectional view taken along line AA′ of FIG. 3A;

FIG. 3C is a cross-sectional view taken along line BB′ of FIG. 3A;

FIG. 3D is a cross-sectional view taken along line CC′ of FIG. 3A;

FIG. 3E to FIG. 3H are schematic diagrams of a liquid level change in drying a pixel printing medium of a pixel printing region of a display substrate according to an exemplary embodiment of the present disclosure;

FIG. 3I is a schematic diagram of a three-dimensional structure of a pixel defining layer of the display substrate in FIG. 3A;

FIG. 4A is a schematic diagram of a plan structure of a pixel defining layer of a display substrate according to another exemplary embodiment of the present disclosure;

FIG. 4B is a cross-sectional view taken along line DD′ of FIG. 4A;

FIG. 4C is a cross-sectional view taken along line EE′ of FIG. 4A;

FIG. 4D is a cross-sectional view taken along line FF′ of FIG. 4A;

FIG. 4E is a schematic diagram of a three-dimensional structure of a pixel defining layer of the display substrate in FIG. 4A;

FIG. 5A is a schematic diagram of a plan structure of a pixel defining layer of a display substrate according to another exemplary embodiment of the present disclosure;

FIG. 5B is a cross-sectional view taken along line GG′ of FIG. 5A;

FIG. 5C is a schematic diagram of a three-dimensional structure of a pixel defining layer of the display substrate in FIG. 5A;

FIG. 6 schematically shows a partial enlarged view of a section of a display substrate according to an exemplary embodiment of the present disclosure;

FIG. 7 is a flowchart of a method of manufacturing a display substrate according to an exemplary embodiment of the present disclosure;

FIG. 8 is a flowchart of operation S10 in a method of manufacturing a display substrate according to an exemplary embodiment of the present disclosure;

FIG. 9 is a schematic diagram of a display device according to an exemplary embodiment of the present disclosure.

It should be noted that, for the sake of clarity, in the accompanying drawings used to describe embodiments of the present disclosure, a size of a layer, a structure, or a region may be enlarged or reduced, that is, the accompanying drawings may not be drawn to actual scales.

### DETAILED DESCRIPTION OF EMBODIMENTS

The technical solutions in some embodiments of the present disclosure will be clearly and completely described below in combination with the accompanying drawings. Obviously, the described embodiments are only part, but not all of embodiments of the present disclosure. Based on embodiments provided by the present disclosure, all other embodiments obtained by those skilled in the art fall within the scope of protection of the present disclosure.

Unless otherwise required in the context, in the entire specification and claims, the term “comprise” and other forms thereof, such as the third-person singular form “comprises” and a present participle form “comprising” are construed as open and inclusive, that is, “including, but not limited to”. In the descriptions of the specification, terms “one embodiment”, “some embodiments”, “exemplary embodiments”, “example”, “specific example, or “some examples” are intended to indicate that specific features, structures, materials, or characteristics related to the embodiment(s) or example(s) are included in at least one embodiment or example of the present disclosure. Schematic representations of the above-mentioned terms are not necessarily refer to the same embodiment(s) or example(s). In addition, the specific features, structures, materials, or characteristics may be included in any one or more embodiments or examples in any suitable manner.

Terms “first” and “second” are only used for descriptive purposes and are not to be construed as indicating or implying a relative importance or implicitly indicating the number of indicated technical features. Thus, features defined by “first” and “second” may explicitly or implicitly include one or more of the features. In the descriptions of embodiments of the present disclosure, unless otherwise specified, a term “plurality” means two or more.

In the descriptions of some embodiments, an expression “connection” and a derivative thereof may be used. For example, when describing some embodiments, a term “electrical connection” may be used to indicate that two or more components are in direct physical or electrical contact with each other.

“At least one of A, B, and C” has the same meaning as “at least one of A, B, or C”, and they both include the following combinations of A, B, and C: only A, only B, only C, a combination of A and B, a combination of A and C, a combination of B and C, and a combination of A, B, and C.

“A and/or B” includes the following three combinations: only A, only B, and a combination of A and B.

“Configured to” as used herein means an open and inclusive language, which does not exclude an apparatus that is applicable for or configured to perform an additional task or step.

In addition, the use of “based on” means an open and inclusive language, since a process, a step, a calculation, or other actions “based on” one or more of said conditions or values may be based on additional conditions or exceed the values in practice.

As used herein, “about” or “approximately” includes a stated value and an average value within an acceptable deviation range of a particular value. The acceptable deviation range is determined by those skilled in the art considering a measurement in discussion and an error (i.e., a limitation of a measurement system) related to a measurement of a particular quantity.

As used herein, “parallel”, “vertical”, and “equal” include a stated situation and a situation similar to the stated situation. A range of the similar situation falls within an acceptable deviation range. The acceptable deviation range is determined by those skilled in the art considering the measurement in discussion and the error (i.e., the limitation of the measurement system) related to the measurement of the particular quantity. For example, the term “parallel” includes absolutely parallel and approximately parallel, wherein an acceptable deviation range of approximately parallel may be within 5°. The term “vertical” includes absolutely vertical and approximately vertical, wherein an acceptable deviation range of approximately vertical may also be within 5°. The term “equal” includes absolutely equal and approximately equal. For example, an acceptable deviation range of approximate equal may be that a difference between the two that are equal is less than or equal to 5% of either.

It should be understood that when a layer or element is referred as being on another layer or substrate, the layer or element may be directly on another layer or substrate, or an intermediate layer may exist between the layer or element and another layer or substrate.

A term “same layer” used herein refers to a layer structure formed by forming a film layer for formation of specific patterns through one and the same film forming process, and then performing a patterning process using a mask. According to different specific patterns, one time patterning process may include a plurality of exposure, development or etching processes. The specific patterns in the formed layer structure may be continuous or discontinuous, and they may also be located at different heights or have different thicknesses. On the contrary, a term “different layers” refers to a layer structure formed by forming film layers for formation of specific patterns through corresponding film forming processes, respectively, and then performing patterning processes using corresponding masks. For example, an expression “two layer structures are arranged in different layers” indicates that two layer structures are respectively formed in corresponding process steps (a film forming process and a patterning process).

Exemplary embodiments are described herein with reference to sectional views and/or plan views that are idealized exemplary drawings. In the drawings, thicknesses of layers and regions are enlarged for clarity. As such, variations from the shapes of the accompanying drawings as a result, for example, of manufacturing techniques and/or tolerances, are to be expected. Therefore, exemplary embodiments should not be construed as being limited to a shape of a region as shown herein, but include a shape deviation due to, for example, manufacturing. For example, an etched region shown as a rectangle may generally have a curved feature. Therefore, the regions shown in the accompanying drawings are schematic in nature and their shapes are not intended to show the actual shapes of the regions of the apparatus and are not intended to limit the scope of the exemplary embodiments.

In embodiments of the present disclosure, a term “accommodating region” refers to a region for accommodating or filling a pixel printing medium, for example, accommodating a redundantly printed pixel printing medium. In the embodiments, the pixel printing medium may be, for example, ink formed by an organic light-emitting material for inkjet printing.

In embodiments of the present disclosure, a term “climbing effect” refers to a phenomenon that due to cohesion and adsorption of a liquid, the liquid may resist a tensile stress and adhere to a surface of other objects, for example, when the liquid is in contact with other objects, the liquid may adhere to the surface of other objects, and meanwhile, due to the cohesion of the liquid, a liquid level with a curved surface may be formed, and due to an effect of surface tension, at a position where the liquid is in contact with the solid, a height of the liquid level is lower than a height of a contact point between the liquid and the solid.

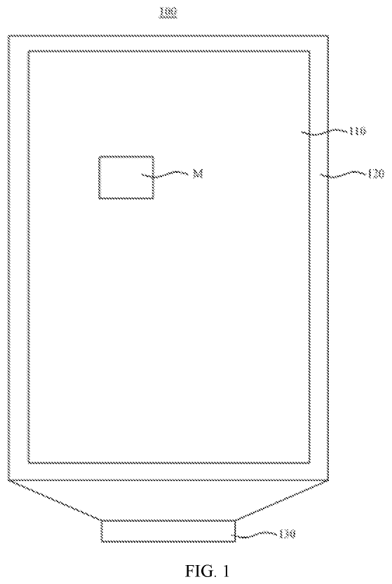

A structure of a display substrate according to embodiments of the present disclosure will be described below in detail in combination with FIG. 1 to FIG. 6.

As shown in FIG. 1, a display substrate 100 includes a display region 110 and a non-display region 120 surrounding the display region 110. The display substrate 100 further includes a bonding region 130 located on a side of the display region 110 and the non-display region 120. The bonding region 130 is used to be electrically connected to other circuits. The display region 110 of the display substrate 100 is provided with a plurality of light-emitting units, and each light-emitting unit is provided with an organic light-emitting material layer. Light of different colors, such as red, blue, green, white and other colors is generated according to a received electrical signal.

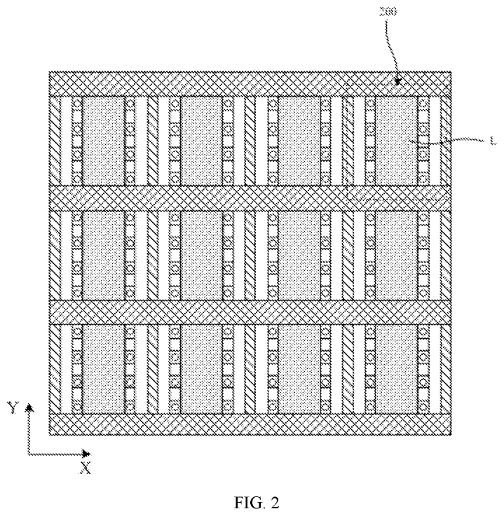

FIG. 2 is a partial enlarged view of an M region of the display substrate shown in FIG. 1.

As shown in FIG. 2, light-emitting units arranged in an array are provided in the display region 110 of the display substrate 100, such as a region in which M is located. Each light-emitting unit includes a plurality of pixel printing regions 200 arranged in an array defined by a pixel defining layer, and the pixel printing region 200 is filled with a pixel light-emitting region L formed by a pixel printing medium. When the pixel light-emitting region L receives an electrical signal, the pixel light-emitting region L emits light for display. The pixel light-emitting region L may generate light of different colors by printing different pixel printing mediums. Alternatively, the pixel light-emitting region L may further generate light of the same color by printing the same pixel printing medium.

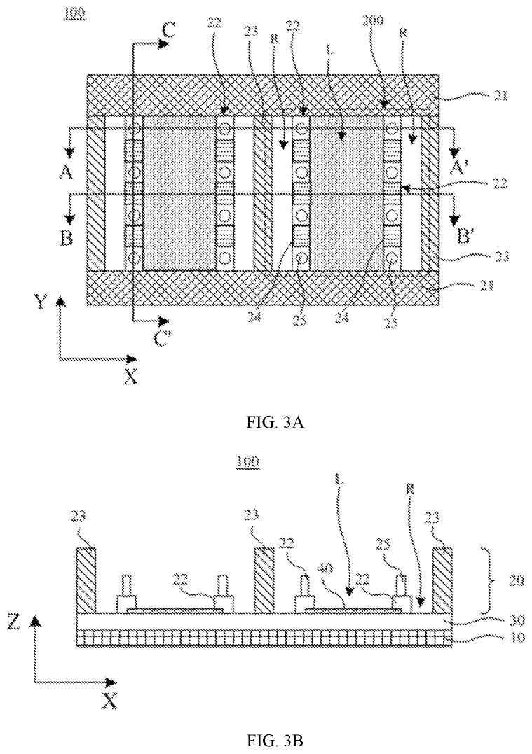

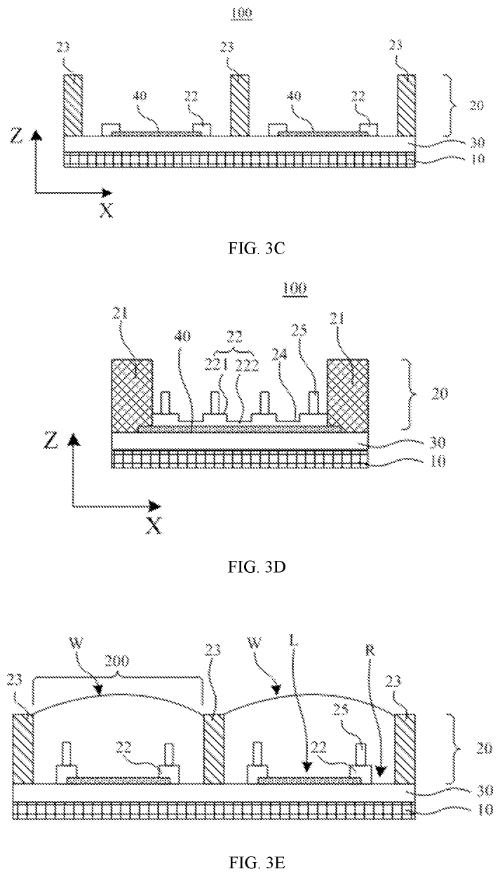

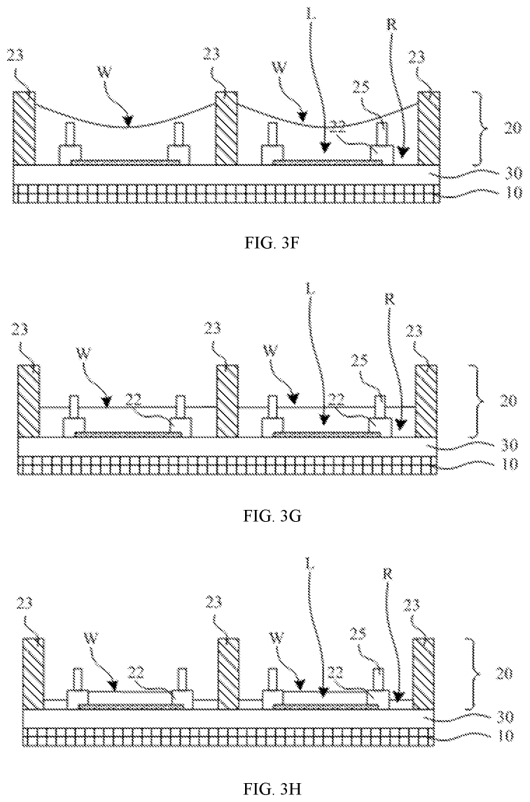

FIG. 3A is a schematic diagram of a plan structure of a pixel defining layer of a display substrate according to an exemplary embodiment of the present disclosure. FIG. 3B is a cross-sectional view taken along line AA′ of FIG. 3A. FIG. 3C is a cross-sectional view taken along line BB′ of FIG. 3A. FIG. 3D is a cross-sectional view taken along line CC′ of FIG. 3A. FIG. 3I is a schematic diagram of a three-dimensional structure of the pixel defining layer of the display substrate in FIG. 3A.

A structure of the display substrate according to the present disclosure will be described below in detail in combination with FIG. 3A to FIG. 3D.

As shown in FIG. 3A to FIG. 3D, a pixel defining layer 20 is formed on a surface of a side of a base substrate 10, and other material layers 30 are formed between the base substrate 10 and the pixel defining layer 20. Other material layers 30 may include, for example, material layers such as a light-shielding layer, a buffer layer, a semiconductor layer, a gate layer, an interlayer dielectric layer, etc. Film thicknesses and the number of film layers of other material layers 30 may be set according to actual needs, which are not limited by embodiments of the present disclosure.

In embodiments of the present disclosure, the pixel defining layer 20 is used to define the plurality of pixel printing regions 200 in a third direction Z on the base substrate 10, the pixel printing region 200 is used to be filled with the pixel printing medium, and the pixel printing medium includes, for example, an inkjet printing ink made of an organic light-emitting material. The plurality of pixel printing regions 200 are arranged in an array in a first direction X and a second direction Y, the first direction X forms an included angle with the second direction Y, and the third direction Z is perpendicular to a plane formed by intersecting the first direction X with the second direction Y.

Exemplarily, as shown in FIG. 2 and FIG. 3A to FIG. 3D, the first direction X is disposed laterally, and the second direction Y is disposed longitudinally. An included angle exists between the first direction X and the second direction Y, that is, the pixel printing regions 200 are arranged according to a design of an actual pixel unit. The first direction X forms an included angle with the second direction Y. For example, the included angle between the first direction X and the second direction Y is an acute angle, an obtuse angle or a right angle. The included angle between the first direction X and the second direction Y may be set according to an arrangement rule of sub-pixels in the actual pixel unit. In the embodiment, the first direction X is disposed perpendicular to the second direction Y. For example, the third direction Z may be a direction perpendicular to a plane on which an upper surface of the base substrate 10 is located, that is, perpendicular to the plane formed by intersecting the first direction X with the second direction Y.

The pixel defining layer 20 defines the pixel printing regions 200 in the third direction of the base substrate 10. In the third direction Z, the pixel printing region 200 has the pixel light-emitting region L enclosed by a first blocking portion 21, a second blocking portion 22.

As shown in FIG. 3A, the pixel defining layer 20 includes a plurality of first blocking portions 21, a plurality of second blocking portions 22 and a plurality of barriers 23. The plurality of first blocking portions 21 are spaced in the second direction Y, that is, the plurality of first blocking portions 21 are arranged at intervals in the second direction Y. A preset spacing exists between adjacent first blocking portions 21, and the preset spacing may be determined according to a size of an actually designed pixel unit. Each first blocking portion 21 is disposed parallel to the first direction X, that is, each first blocking portion 21 extends in the first direction X. The plurality of second blocking portions 22 are spaced in the first direction X, that is, the plurality of second blocking portions 22 are arranged at intervals in the first direction. A preset spacing exists between adjacent second blocking portions 22, and the preset spacing may also be determined according to the size of the actually designed pixel unit. Each second blocking portion 22 is disposed parallel to the second direction, that is, each second blocking portion 22 extends in the second direction Y. The plurality of barriers 23 are spaced in the first direction X, that is, the plurality of barriers 23 are arranged at intervals in the first direction X. A preset spacing exists between adjacent barriers 23. Each barrier 23 extends in the second direction Y, and the barrier 23 is disposed between the adjacent second blocking portions 22. The first blocking portions 21 and the barriers 23 surround to form the plurality of pixel printing regions 200 arranged in an array.

In embodiments of the present disclosure, the first blocking portion 21 and the second blocking portion 22 surround to form the pixel light-emitting region L. For example, two adjacent first blocking portions 21 extending in the first direction X and two adjacent second blocking portions 22 extending in the second direction Y surround to form the light-emitting region L. In the second direction Y, the barrier 23 is disposed between the second blocking portions 22 of the adjacent pixel printing regions 200. For example, the barrier 23 is provided in the second direction Y between two adjacent pixel printing regions 200, so as to separate the two adjacent pixel printing regions 200.

In embodiments of the present disclosure, the display substrate 100 further includes a plurality of accommodating regions R disposed on the base substrate 10, at least one accommodating region R is located between the adjacent first blocking portions 21 in the second direction Y, and between adjacent second blocking portion 22 and barrier 23 in the first direction X.

Exemplarily, as shown in FIG. 3A to FIG. 3D, the accommodating region R is located on the base substrate 10. The first blocking portions 21, the second blocking portions and the barriers 23 surround to form the accommodating regions R. The accommodating regions R are located on two sides of the pixel light-emitting region L, respectively.

In embodiments of the present disclosure, the pixel printing region 200 includes the pixel light-emitting region L and the accommodating regions R. For example, each pixel printing region 200 may include two accommodating regions R on the two sides and the pixel light-emitting region L between the two accommodating regions R.

In embodiments of the present disclosure, the display substrate 100 further includes a first diversion structure disposed on a side of the second blocking portion 22 away from the base substrate 10. The first diversion structure is used to divert a part of the pixel printing medium filled in the pixel light-emitting region L to the accommodating region R adjacent to the pixel light-emitting region L.

Exemplarily, as shown in FIG. 3D, the first diversion structure includes a plurality of first diversion trenches 24 provided on the second blocking portion 22. The first diversion trenches 24 are spaced on a side of the second blocking portion 22 away from the base substrate 10. As shown in FIG. 3A, each first diversion trench 24 has two opposite ends, one end is connected to the pixel light-emitting region L and the other end is connected to the accommodating region R.

According to embodiments of the present disclosure, the pixel printing region 200 may include the pixel light-emitting region L and the accommodating regions R. A part of the pixel printing medium redundant in the light-emitting region may be diverted to the accommodating region R through the first diversion structure (such as the first diversion trench 24) by providing the light-emitting region L and the accommodating region R in the pixel printing region 200 and providing the first diversion structure between the light-emitting region L and the accommodating region, which may effectively avoid an occurrence of an uneven liquid level and an uneven thickness of the pixel printing medium in the pixel light-emitting region L, thus improving a consistency of a film thickness of the pixel light-emitting region L of the display substrate, and effectively improving a display effect and a yield of the display substrate.

As shown in FIG. 3A and FIG. 3D, the first diversion trench 24 has a recessed structure. When printing the pixel printing region, the pixel printing medium fills the pixel printing region 200. The pixel printing medium may cover the pixel defining layer 20 due to an effect of surface tension, and due to an existence of the first blocking portion 21 and the barrier 23, the pixel printing medium may not interfere with each other in the pixel printing region 200. After the pixel printing medium is dried in the pixel printing region, the pixel printing medium in the pixel light-emitting region L emits light when receiving the electrical signal, so that an effect of light-emitting display is realized.

As shown in FIG. 3D, the second blocking portion 22 includes thickened portions 21 that are spaced apart from each other and thinned portions 222 that are spaced apart from each other. A thickness of each thickened portion 221 in the third direction Z is greater than a thickness of each thinned portion.

For example, a plurality of thickened portions 221 are spaced, and a plurality of thinned portions 222 are spaced, so as to form the first diversion trenches 24 with the recessed structure, opposite side surfaces of two adjacent thickened portions 221 form sidewalls of the first diversion trench 24, and a top surface of the thinned portion 222 away from the base substrate forms a bottom wall of the first diversion trench 24. The first diversion trench 24 is used to divert a part of the pixel printing medium filled in the pixel light-emitting region L to the accommodating region R adjacent to the pixel light-emitting region L, so as to realize an effect of diversion, so that the pixel printing medium in the pixel light-emitting region L may have a uniform and consistent film thickness.

In embodiments of the present disclosure, the display substrate further includes a liquid level adjusting structure disposed on at least one of the first blocking portion and the second blocking portion. The liquid level adjusting structure is used to adjust the pixel printing medium in the pixel light-emitting region, so that the pixel printing medium in the pixel light-emitting region may form a flat liquid level.

In embodiments of the present disclosure, in a drying process after the pixel printing medium is printed, a surface of a film layer formed after drying is uneven due to the effect of surface tension. In order to solve a problem of the uneven surface of the film layer formed in the drying process of the pixel printing medium, the present disclosure may realize an adjustment of the liquid level of the pixel printing medium by providing the liquid level adjusting structure, so that the pixel printing medium in the pixel light-emitting region may form the flat liquid level in the drying process.

The liquid level adjusting structure includes a first liquid level adjusting structure disposed on the first blocking portion 21. The first liquid level adjusting structure includes: a plurality of recessed portions spaced on a side surface of the first blocking portion facing the pixel light-emitting region.

The liquid level adjusting structure further includes a second liquid level adjusting structure disposed on the second blocking portion 22. The second liquid level adjusting structure includes: a cylindrical structure disposed on a side of the second blocking portion away from the base substrate and extending in the third direction.

Exemplarily, the liquid level adjusting structure may be the first liquid level adjusting structure disposed on the first blocking portion 21 or the second liquid level adjusting structure disposed on the second blocking portion 22. The first liquid level adjusting structure and the second liquid level adjusting structure may be provided at the same time, or either of them may be provided, which is not limited by embodiments of the present disclosure.

FIG. 3E to FIG. 3H are schematic diagrams of a liquid level change in drying the pixel printing medium of the pixel printing region of the display substrate according to an exemplary embodiment of the present disclosure. FIG. 3A to FIG. 3H show the second liquid level adjusting structure disposed on the second blocking portion.

An adjustment process of the second liquid level adjusting structure of the display substrate according to the embodiment of the present disclosure will be described below in detail in combination with FIG. 3A to FIG. 3I.

As shown in FIG. 3A to FIG. 3D, the liquid level adjusting structure includes the second liquid level adjusting structure 25 disposed on the second blocking portion 22, the second liquid level adjusting structure 25 includes the cylindrical structure disposed on a side of the second blocking portion 22 away from the base substrate 10 and extending in the third direction Z. For example, the cylindrical structure is disposed on a side of an upper surface of the thickened portion 221 of the second blocking portion 22 away from the base substrate.

Exemplarily, a diameter of the cylindrical structure is in a range of 1 μm to 3 μm, and a height of the cylindrical structure in the third direction Z is in a range of 0.2 μm to 0.4 μm.

Exemplarily, a manufacturing material of the cylindrical structure may be a resin material or an inorganic material (SiO, SiNx, etc.).

As shown in FIG. 3E, the pixel printing medium W is ink-jet printed in the pixel printing region 200, and the pixel printing medium W fills the pixel printing region 200. Due to the effect of surface tension, an upper side of the liquid level of the pixel printing medium forms an upwardly protruded curved surface, which is covered on the pixel defining layer 20. The pixel printing regions 200 may not interfere with each other through a blocking of the first blocking portion 21 and the barrier 23.

As shown in FIG. 3F, in the drying process of the pixel printing medium W, the liquid level of the pixel printing medium W drops gradually. Due to the climbing effect existing between the pixel printing medium W and the first blocking portion 21 and the barrier 23, the liquid level of the pixel printing medium W exhibits a downwardly recessed shape. By providing the second liquid level adjusting structure 25, when the liquid level of the pixel printing medium W drops to a same height as a height of the second liquid level adjusting structure 25, the second liquid level adjusting structure 25 may destroy a surface tension of the pixel printing medium W, so that the climbing effect is inhibited.

As shown in FIG. 3G, when the liquid level of the pixel printing medium W drops below the height of the second liquid level adjusting structure 25, the climbing effect of the liquid level is destroyed, so that a thickness of the liquid level of the pixel printing medium in the pixel printing region remains the same.

As shown in FIG. 3H, when the pixel printing medium W continues to be dried, a part of the pixel printing medium in the pixel light-emitting region L may be diverted to the accommodating region R adjacent to the pixel light-emitting region L by forming the first diversion structure 24 on a side of the second blocking portion 22 away from the base substrate, so that a thickness of a film layer formed by the pixel printing medium in the pixel light-emitting region L is uniform and consistent.

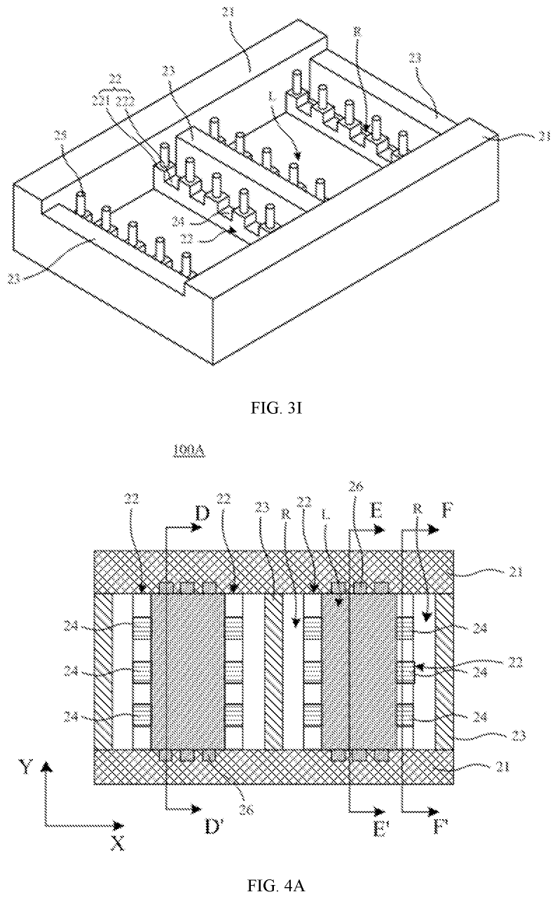

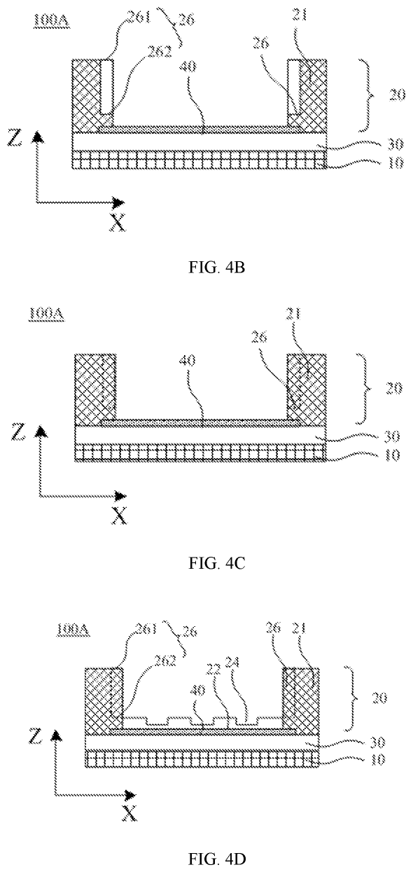

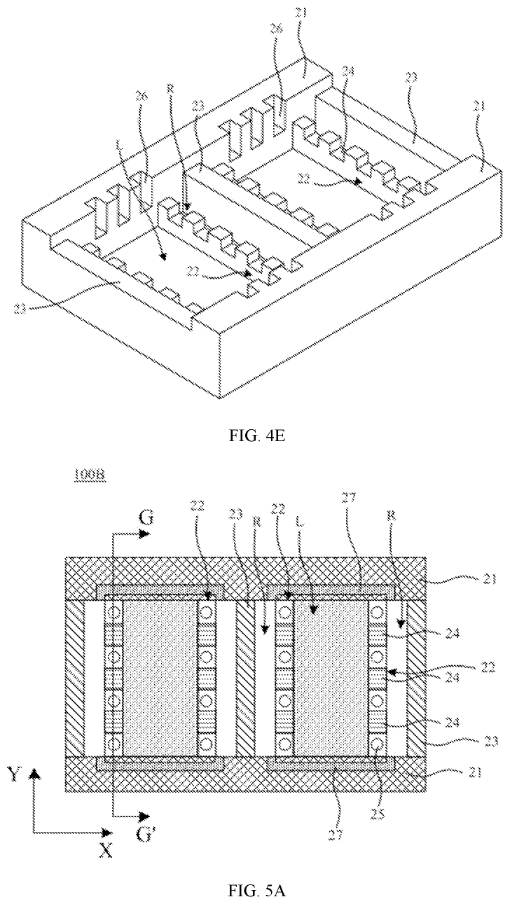

FIG. 4A is a schematic diagram of a plan structure of a pixel defining layer of a display substrate according to another exemplary embodiment of the present disclosure. FIG. 4B is a cross-sectional view taken along line DD′ of FIG. 4A. FIG. 4C is a cross-sectional view taken along line EE′ of FIG. 4A. FIG. 4D is a cross-sectional view taken along line FF′ of FIG. 4A. FIG. 4E is a schematic diagram of a three-dimensional structure of the pixel defining layer of the display substrate in FIG. 4A.

As shown in FIG. 4A to FIG. 4D, a pixel defining layer 20 of a display substrate 110A in the embodiment includes a first blocking portion 21, a second blocking portion 22 and a barrier 23. As in other embodiments, the first blocking portion 21 and the second blocking portion 22 surround to form a pixel light-emitting region L, and the first blocking portions adjacent to each other in the second direction Y, the second blocking portion 22 and the barrier 23 adjacent to each other in the first direction X surround to form an accommodating region R. A first diversion structure 24 is provided on a side of the second blocking portion 22 away from the base substrate, and the first diversion structure 24 is used to divert a part of the pixel printing medium filled in the pixel light-emitting region L to the accommodating region R adjacent to the pixel light-emitting region L. In the embodiment, a liquid level adjusting structure of the display substrate 100A includes a first liquid level adjusting structure disposed on the first blocking portion 21.

Exemplarily, the first liquid level adjusting structure includes a plurality of recessed portions 26, and the plurality of recessed portions 26 are spaced on a side surface of the first blocking portion 21 facing the pixel light-emitting region L. As shown in FIG. 4B, the recessed portion 26 includes a recessed portion opening 261 and a recessed portion bottom surface 262. The recessed portion opening is disposed on a side surface of the first blocking portion 21 away from the base substrate, and the recessed portion opening faces the first direction X and the third direction Z, that is, the recessed portion openings 261 between the adjacent first blocking portions 21 are disposed opposite to each other. The recessed portion opening 261 of each recessed portion 26 is located on the first blocking portion 21 toward a direction away from the base substrate 10.

As shown in FIG. 4D, the recessed portion bottom surface 262 is disposed between the side surface of the first blocking portion 21 away from the base substrate and a side surface of the first blocking portion 21 close to the base substrate. The recessed portion bottom surface 262 is located in a same plane as an upper surface of the second blocking portion 22 away from the base substrate. That is, in the third direction Z, the recessed portion bottom surface 262 has a same height as that of the upper surface of the second blocking portion 22, or a height difference between the recessed portion bottom surface 262 and the upper surface of the second blocking portion 22 is within a preset threshold, for example, the height difference is in a range of 0 μm to 1 μm. The liquid level of the pixel printing medium in the pixel light-emitting region L may be adjusted by providing the plurality of recessed portions 26, so that the pixel printing medium in the pixel light-emitting region may form a flat liquid level.

Exemplarily, a width of the recessed portion opening 261 in the first direction X is in a range of 1 μm to 2 μm, and a depth of the recessed portion opening 261 in the second direction Y is in a range of 1 μm to 3 μm.

In embodiments of the present disclosure, by providing the first liquid level adjusting structure on the first blocking portion 21, the second liquid level adjusting structure does not need to be provided on the second blocking portion. In other optional embodiments, the first liquid level adjusting structure and the second liquid level adjusting structure may be provided at the same time, so as to better adjust the liquid level of the pixel printing medium in the pixel light-emitting region and ensure that a film layer formed on a surface of the pixel light-emitting region has a good thickness uniformity.

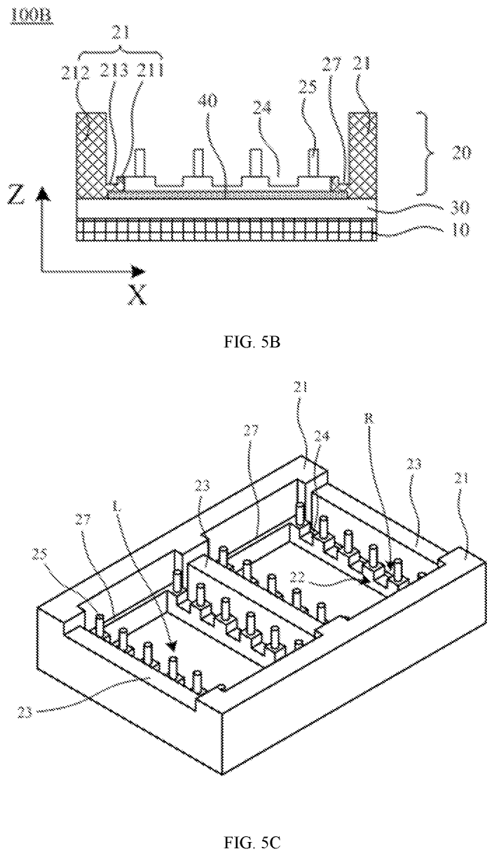

FIG. 5A is a schematic diagram of a plan structure of a pixel defining layer of a display substrate according to another exemplary embodiment of the present disclosure. FIG. 5B is a cross-sectional view taken along line GG′ of FIG. 5A. FIG. 5C is a schematic diagram of a three-dimensional structure of a pixel defining layer of the display substrate in FIG. 5A.

In embodiments of the present disclosure, a display substrate 100B includes a first blocking portion 21, a second blocking portion 22, and a barrier 23. The second blocking portion 22 is provided with a first diversion structure, and the first diversion structure may be, for example, a first diversion trench 24. The second blocking portion 22 is further provided with a second liquid level adjusting structure 25, and the second liquid level adjusting structure may be, for example, a cylindrical structure. In addition, the display substrate 100B further includes a second diversion structure disposed on a side surface of the first blocking portion 21 facing the pixel light-emitting region L, and the second diversion structure is used to divert a part of the pixel printing medium filled in the pixel light-emitting region L to the accommodating region R.

Exemplarily, as shown in FIG. 5A and FIG. 5B, the second diversion structure includes a second diversion trench 27 disposed in the first blocking portion 21 in the first direction X, and each end of the second diversion trench 27 is respectively connected to the accommodating regions R adjacent to the pixel light-emitting region L. That is, a length direction of the second diversion trench 27 is parallel to the first direction X.

In embodiments of the present disclosure, the first blocking portion 21 includes a first blocking sub-portion 211, a second blocking sub-portion 212 and a third blocking sub-portion 213. The first blocking sub-portion 211 is close to the pixel light-emitting region L, the second blocking sub-portion 212 is away from the pixel light-emitting region L, and the third blocking sub-portion 213 is located between the first blocking sub-portion 211 and the second blocking sub-portion 213. In the third direction Z, a thickness of the second blocking sub-portion 212 is greater than a thickness of the first blocking sub-portion 211, and the thickness of the first blocking portion sub-portion 211 is greater than a thickness of the third blocking portion sub-portion 213.

The first blocking sub-portion 211 and the second blocking sub-portion 212 respectively form two sidewalls of the second diversion trench 27, and the third blocking sub-portion 213 forms a bottom wall of the second diversion trench 27. For example, the second diversion trench 27 is formed by the first blocking sub-portion 211, the second blocking sub-portion 212 and the third blocking sub-portion 213.

In embodiments of the present disclosure, an upper surface of the first blocking sub-portion 211 in the third direction Z is located in a same plane as an upper surface of the first diversion trench 24 of the first diversion structure in the third direction Z. That is, in the third direction Z, the first blocking sub-portion 211 has a same height as that of the first diversion structure, and specifically, the upper surface the first blocking sub-portion 211 has a same height as that of the upper surface of the second blocking portion 22. The bottom wall of the second diversion trench 27 is located in a same plane as the bottom wall of the first diversion trench 24. That is, in the third direction Z, a depth of the first diversion trench 24 is consistent with that of the second diversion trench 27.

In embodiments of the present disclosure, as shown in FIG. 3B to FIG. 3H, FIG. 4B to FIG. 4D and FIG. 5B, the display substrate further includes an anode material layer 40, and the anode material layer 40 is disposed between the base substrate 10 and the pixel defining layer 20. An orthographic projection of at least one of the first blocking portion 21 and the second blocking portion 22 on the base substrate 10 forms an overlapping region with an orthographic projection of the anode material layer 40 on the base substrate 10.

Exemplarily, a part of the anode material layer 40 is in contact with a part of the first blocking portion 21 and the second blocking portion 22, respectively, so as to realize a protection of an edge of the anode material layer 40.

In embodiments of the present disclosure, at least part of an orthographic projection of the liquid level adjusting structure on the base substrate is located in the overlapping region; and/or at least part of an orthographic projection of the second diversion trench on the base substrate is located in the overlapping region.

Exemplarily, the liquid level adjusting structure may include the first liquid level adjusting structure (such as the cylindrical structure) and the second liquid level adjusting structure (such as the recessed portion 26). At least part of an orthographic projection of at least one of the first liquid level adjusting structure and the second liquid level adjusting structure is located in the overlapping region, which may ensure that a part of the first blocking portion and the second blocking portion at least overlaps the anode material layer, so as to realize a protection of the anode material layer.

In embodiments of the present disclosure, orthographic projections of the plurality of barriers on the base substrate do not overlap the orthographic projection of the anode material layer on the base substrate. Therefore, a certain spacing exists between the barrier and the second blocking portion to form the accommodating region so as to accommodate the redundant pixel printing medium.

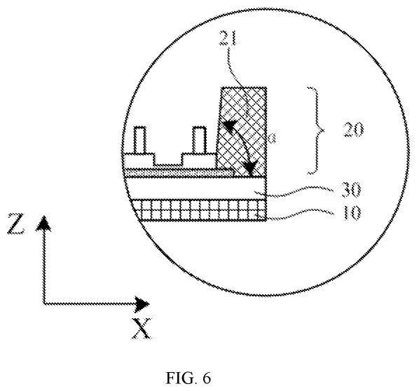

FIG. 6 schematically shows a partial enlarged view of a section of a display substrate according to an exemplary embodiment of the present disclosure.

In embodiments of the present disclosure, as shown in FIG. 6, a side of the first blocking portion facing the pixel light-emitting region forms an included angle α with a plane formed by intersecting the first direction X with the second direction Y, and the included angle α is less than or equal to 90 degrees.

In embodiments of the present disclosure, in the third direction Z, a height of the first blocking portion 21 is greater than a height of the barrier 23, and the height of the barrier 23 is greater than a height of the second blocking portion 22.

For example, the height of the first blocking portion is in a range of 1 μm to 2.5 μm, and the height of the barrier is in a range of 0.7 μm to 2.25 μm.

For example, the first blocking portion extends in the first direction X, a width of the first blocking portion in the second direction Y is in a range of 9 μm to 12 μm. For example, the width may be set to 10 μm.

For example, the second blocking portion extends in the second direction Y, a width of the second blocking portion in the first direction X is in a range of 1 μm to 3 μm, the height of the second blocking portion in the third direction Z is in a range of 0.3 μm to 0.8 μm. For example, the height may be set to 0.6 μm.

For example, the barrier extends in the second direction Y, a width of the barrier in the first direction X is in a range of 0.5 μm to 3 μm, and the height of the barrier in the third direction Z is 1.2 to 1.5 times the height of the second blocking portion.

In the embodiments, a width of the first diversion trench in the second direction Y is in a range of 3 μm to 6 μm, and the depth of the first diversion trench in the third direction Z is in a range of 0.25 μm to 0.35 μm. For example, the first diversion trench may be made by a halftone process.

Another aspect of the present disclosure provides a method of manufacturing a display panel. The display panel manufactured by the method includes the display substrate as described above.

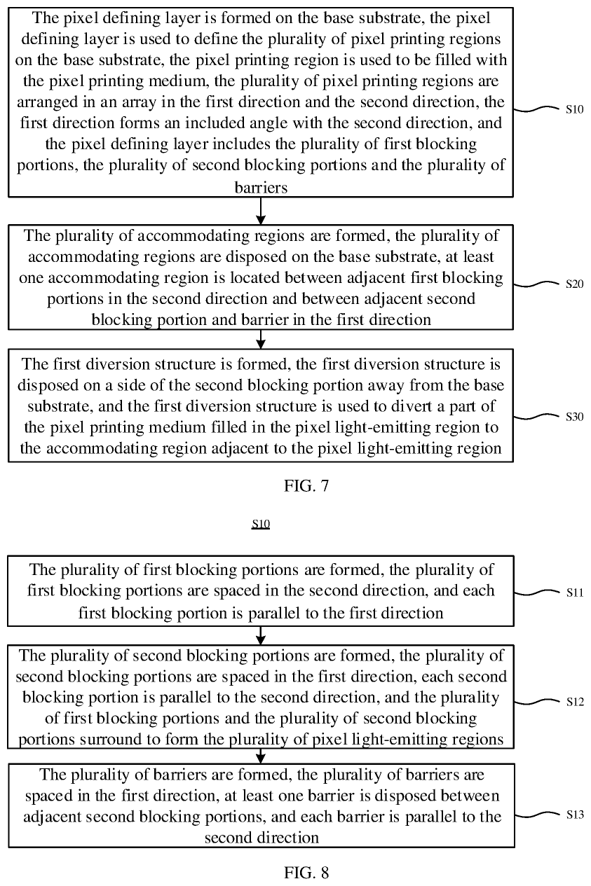

FIG. 7 is a flowchart of a method of manufacturing a display substrate according to an exemplary embodiment of the present disclosure.

The manufacturing method of the present disclosure will be described below in detail in combination with FIG. 7.

As shown in FIG. 7, the method includes operations S10 to S30.

Referring to FIG. 3A to FIG. 3D, in operation S10, the pixel defining layer 20 is formed on the base substrate, the pixel defining layer is used to define the plurality of pixel printing regions 200 on the base substrate, the pixel printing region 200 is used to be filled with the pixel printing medium, the plurality of pixel printing regions are arranged in an array in the first direction X and the second direction Y, the first direction X forms an included angle with the second direction Y, and the pixel defining layer includes the plurality of first blocking portions 21, the plurality of second blocking portions 22 and the plurality of barriers 23.

Exemplarily, the pixel defining layer 20 may define the plurality of pixel printing regions in the third direction on the base substrate. The third direction Z is perpendicular to the plane formed by intersecting the first direction X with the second direction Y.

Exemplarily, the plurality of first blocking portions and the plurality of second blocking portions surround to form the plurality of pixel light-emitting regions L by forming the plurality of first blocking portions 21, the plurality of second blocking portions 22 and the plurality of barriers 23 on the base substrate.

FIG. 8 is a flowchart of operation S10 in a method of manufacturing a display substrate according to an exemplary embodiment of the present disclosure.

As shown in FIG. 8, operation S10 includes operations S11 to S13.

In operation S11, the plurality of first blocking portions 21 are formed, the plurality of first blocking portions 21 are spaced in the second direction Y, and each first blocking portion 21 is parallel to the first direction X.

In operation S12, the plurality of second blocking portions 22 are formed, the plurality of second blocking portions 22 are spaced in the first direction X, each second blocking portion 22 is parallel to the second direction Y, and the plurality of first blocking portions 21 and the plurality of second blocking portions 22 surround to form the plurality of pixel light-emitting regions L.

In operation S13, the plurality of barriers 23 are formed, the plurality of barriers 23 are spaced in the first direction X, at least one barrier is disposed between adjacent second blocking portions 22, and each barrier is parallel to the second direction Y.

In operation S20, the plurality of accommodating regions R are formed, the plurality of accommodating regions R are disposed on the base substrate 10, at least one accommodating region R is located between adjacent first blocking portions 21 in the second direction Y, and between the adjacent second blocking portions 22 and the barrier 23 in the first direction X.

In embodiments of the present disclosure, the first blocking portion 21, the second blocking portion 22 and the barrier 23 may together surround to form the accommodating region R by designing positions in which the first blocking portion 21, the second blocking portion 22 and the barrier 23 are formed. The accommodating regions R are located on two sides of the pixel display region L, and are used to accommodate the redundant pixel printing medium.

In operation S30, the first diversion structure is formed, the first diversion structure is disposed on a side of the second blocking portion away from the base substrate, and the first diversion structure is used to divert a part of the pixel printing medium filled in the pixel light-emitting region to the accommodating region R adjacent to the pixel light-emitting region.

In embodiments of the present disclosure, by forming the first diversion structure, a part of the pixel printing medium redundant in the pixel light-emitting region L may be effectively diverted to the accommodating region R adjacent to the pixel light-emitting region L, so that the film layer formed by the pixel printing medium in the pixel light-emitting region L has a uniform thickness.

Exemplarily, the formed first diversion structure includes the plurality of first diversion trenches 24 spaced on a side of the second blocking portion away from the base substrate. An end of each first diversion trench 24 is connected to the pixel light-emitting region L, and the other end of each first diversion trench 24 is connected to the accommodating region R. The second blocking portion 22 includes the plurality of thickened portions 221 that are spaced apart from each other and the plurality of thinned portions 222 that are spaced apart from each other. The thickness of each thickened portion in the third direction is greater than the thickness of each thinned portion. Opposite side surfaces of two adjacent thickened portions form the sidewall of the first diversion trench, and the top surface of the thinned portion away from the base substrate forms the bottom wall of the first diversion trench.

In embodiments of the present disclosure, the manufacturing method further includes forming the liquid level adjusting structure. The liquid level adjusting structure is disposed on at least one of the first blocking portion and the second blocking portion, and the liquid level adjusting structure is used to adjust the pixel printing medium in the pixel light-emitting region, so that the pixel printing medium in the pixel light-emitting region forms a flat liquid level.

Forming the liquid level adjusting structure includes forming the first liquid level adjusting structure on the first blocking portion. The first liquid level adjusting structure includes: the plurality of recessed portions spaced on a side surface of the first blocking portion facing the pixel light-emitting region.

Forming the liquid level adjusting structure further includes forming the second liquid level adjusting structure on the second blocking portion. The second liquid level adjusting structure includes: the cylindrical structure disposed on a side of the second blocking portion away from the base substrate and extending in the third direction.

In embodiments of the present disclosure, the manufacturing method further includes forming the second diversion structure. The second diversion structure is disposed on a side surface of the first blocking portion facing the pixel light-emitting region, and the second diversion structure is used to divert a part of the pixel printing medium filled in the pixel light-emitting region to the accommodating region.

In embodiments of the present disclosure, the method further includes printing the pixel printing medium (containing a light-emitting material for forming the pixel light-emitting layer) by printing in the plurality of pixel printing regions defined by the pixel defining layer. For example, the pixel printing medium is printed in the pixel light-emitting region of the pixel printing region. A part of the pixel printing medium filled in the pixel printing region is diverted to the accommodating region adjacent to the pixel light-emitting region through the first diversion structure disposed on a side of the second blocking portion away from the base substrate, so that the pixel light-emitting layer formed in the pixel light-emitting region has a uniform film thickness, and the display effect is further improved.

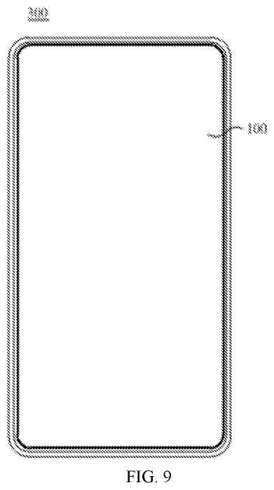

FIG. 9 is a schematic diagram of a display device according to an exemplary embodiment of the present disclosure.

As shown in FIG. 9, a display device 300 includes the display substrate 100 as described above.

The display device 300 in the above-mentioned embodiments of the present disclosure may achieve a beneficial effect which is the same as the beneficial effect of the display substrate 100, which will not be repeated here.

The above-mentioned display device 300 may be any device that displays either a moving (e. g., a video) or fixed (e. g., a still image) text or image. More specifically, it is expected that the embodiments may be implemented in or associated with a plurality of electronic devices. For example, the plurality of electronic devices include (but not limited to) a mobile phone, a wireless device, a personal data assistant (PDA), a handheld or portable computer, a GPS receiver/navigator, a camera, an MP4 video player, a video camera, a game console, a watch, a clock, a calculator, a television monitor, a tablet display, a computer monitor, a car display (e.g. an odometer display, etc.), a navigator, a cockpit controller and/or display, a display for a camera view (e.g., a display of a rear-view camera in a vehicle), an electronic photo, an electronic billboard or indicator, a projector, a building structure, a packaging, an aesthetic structure (e.g., a display for an image of a piece of jewelry), etc.

Although some embodiments of the general concept of the present disclosure have been illustrated and described, those of ordinary skill in the art will understand that these embodiments may be changed without departing from the principle and spirit of the general concept of the present disclosure, and the scope of protection of the present disclosure is defined by claims and their equivalents.

1. A display substrate, comprising:
a base substrate; and
a pixel defining layer configured to define a plurality of pixel printing regions on the base substrate, wherein the pixel printing region is configured to be filled with a pixel printing medium, the plurality of pixel printing regions are arranged in an array in a first direction and a second direction, and the first direction forms an included angle with the second direction;
wherein the pixel defining layer comprises:
a plurality of first blocking portions spaced in the second direction, wherein each first blocking portion is parallel to the first direction;
a plurality of second blocking portions spaced in the first direction, wherein each second blocking portion is parallel to the second direction, and the plurality of first blocking portions and the plurality of second blocking portions surround to form a plurality of pixel light-emitting regions; and
a plurality of barriers spaced in the first direction, wherein at least one barrier is disposed between adjacent second blocking portions, and each barrier is parallel to the second direction;
wherein the display substrate further comprises a plurality of accommodating regions disposed on the base substrate, at least one accommodating region is located between adjacent first blocking portions in the second direction and between adjacent second blocking portion and barrier in the first direction; and
wherein the display substrate further comprises a first diversion structure disposed on a side of the second blocking portion away from the base substrate, and the first diversion structure is configured to divert a part of the pixel printing medium filled in the pixel light-emitting region to the accommodating region adjacent to the pixel light-emitting region.

2. The display substrate according to claim 1,
wherein the first diversion structure comprises a plurality of first diversion trenches spaced on a side of the second blocking portion away from the base substrate, an end of each first diversion trench is connected to the pixel light-emitting region, and the other end of each first diversion trench is connected to the accommodating region.

3. The display substrate according to claim 2,
wherein the second blocking portion comprises a plurality of thickened portions that are spaced apart from each other and a plurality of thinned portions that are spaced apart from each other, a thickness of each thickened portion in a third direction is greater than a thickness of each thinned portion, and the third direction is perpendicular to a plane formed by intersecting the first direction with the second direction.

4. The display substrate according to claim 3,
wherein opposite sides of two adjacent thickened portions form sidewalls of the first diversion trench, and a top surface of the thinned portion away from the base substrate forms a bottom wall of the first diversion trench.

5. The display substrate according to claim 4,
wherein the display substrate further comprises a liquid level adjusting structure disposed on at least one of the first blocking portion and the second blocking portion, and the liquid level adjusting structure is configured to: adjust the pixel printing medium in the pixel light-emitting region, so that the pixel printing medium in the pixel light-emitting region forms a flat liquid level.

6. The display substrate according to claim 5,
wherein the liquid level adjusting structure comprises a first liquid level adjusting structure disposed on the first blocking portion, and the first liquid level adjusting structure comprises: a plurality of recessed portions spaced on a side surface of the first blocking portion facing the pixel light-emitting region.

7. The display substrate according to claim 6,
wherein the recessed portion comprises a recessed portion opening and a recessed portion bottom surface, the recessed portion opening is disposed on a side surface of the first blocking portion away from the base substrate, and the recessed portion opening faces the second direction and the third direction; and
wherein the recessed portion bottom surface is disposed between the side surface of the first blocking portion away from the base substrate and a side surface of the first blocking portion close to the base substrate, and the recessed portion bottom surface is located in a same plane as an upper surface of the second blocking portion away from the base substrate.

8. The display substrate according to claim 5,
wherein the liquid level adjusting structure comprises a second liquid level adjusting structure disposed on the second blocking portion, and the second liquid level adjusting structure comprises:
a cylindrical structure disposed on a side of the second blocking portion away from the base substrate and extending in the third direction; and
wherein the cylindrical structure is disposed on an upper surface of at least one thickened portion away from the base substrate.

9. The display substrate according to claim 5,
wherein the display substrate further comprises a second diversion structure disposed on a side surface of the first blocking portion facing the pixel light-emitting region, and the second diversion structure is configured to: divert a part of the pixel printing medium filled in the pixel light-emitting region to the accommodating region.

10. The display substrate according to claim 9,
wherein the second diversion structure comprises: a second diversion trench disposed at the first blocking portion in the first direction, and each end of the second diversion trench is respectively connected to the accommodating regions adjacent to the pixel light-emitting region.

11. The display substrate according to claim 10,
wherein the first blocking portion comprises:
a first blocking sub-portion close to the pixel light-emitting region;
a second blocking sub-portion away from the pixel light-emitting region; and
a third blocking sub-portion located between the first blocking sub-portion and the second blocking sub-portion; and
wherein in the third direction, a thickness of the second blocking sub-portion is greater than a thickness of the first blocking sub-portion, and the thickness of the first blocking sub-portion is greater than a thickness of the third blocking sub-portion.

12. The display substrate according to claim 11,
wherein the first blocking portion and the second blocking portion respectively form two sidewalls of the second diversion trench, and the third blocking portion forms a bottom wall of the second diversion trench.

13. The display substrate according to claim 12, wherein an upper surface of the first blocking portion in the third direction is located in a same plane as an upper surface of the second blocking portion in the third direction; and
wherein the bottom wall of the second diversion trench is located in a same plane as the bottom wall of the first diversion trench.

14. The display substrate according to claim 13,
wherein the display substrate further comprises an anode material layer, the anode material layer is disposed between the base substrate and the pixel defining layer, and an orthographic projection of at least one of the first blocking portion and the second blocking portion on the base substrate forms an overlapping region with an orthographic projection of the anode material layer on the base substrate.

15. The display substrate according to claim 14, wherein at least part of an orthographic projection of the liquid level adjusting structure on the base substrate is located in the overlapping region; and/or
at least part of an orthographic projection of the second diversion trench on the base substrate is located in the overlapping region; and
wherein orthographic projections of the plurality of barriers on the base substrate do not overlap with the orthographic projection of the anode material layer on the base substrate.

16. The display substrate according to claim 1,
wherein a side of the first blocking portion facing the pixel light-emitting region forms an included angle with a plane formed by intersecting the first direction with the second direction, and the included angle is less than or equal to 90 degrees.

17. The display substrate according to claim 3,
wherein in the third direction, a height of the first blocking portion is greater than a height of the barrier, and the height of the barrier is greater than a height of the second blocking portion.

18. A method of manufacturing a display substrate, comprising:
forming a pixel defining layer on a base substrate, wherein the pixel defining layer is configured to define a plurality of pixel printing regions on the base substrate, the pixel printing region is configured to be filled with a pixel printing medium, the plurality of pixel printing regions are arranged in an array in a first direction and a second direction, and the first direction forms an included angle with the second direction;
wherein the forming a pixel defining layer comprises:
forming a plurality of first blocking portions spaced in the second direction, wherein each first blocking portion is parallel to the first direction;
forming a plurality of second blocking portions spaced in the first direction, wherein each second blocking portion is parallel to the second direction, and the plurality of first blocking portions and the plurality of second blocking portions surround to form a plurality of pixel light-emitting regions; and
forming a plurality of barriers spaced in the first direction, wherein at least one barrier is disposed between adjacent second blocking portions, and each barrier is parallel to the second direction;
wherein the method further comprises forming a plurality of accommodating regions disposed on the base substrate, at least one accommodating region is located between adjacent first blocking portions in the second direction and between adjacent second blocking portion and barrier in the first direction; and
wherein the method further comprises forming a first diversion structure disposed on a side of the second blocking portion away from the base substrate, and the first diversion structure is configured to divert a part of the pixel printing medium filled in the pixel light-emitting region to the accommodating region adjacent to the pixel light-emitting region.

19. A display device, comprising: the display substrate according to claim 1.

20. The method according to claim 18, wherein the first diversion structure comprises a plurality of first diversion trenches spaced on a side of the second blocking portion away from the base substrate, an end of each first diversion trench is connected to the pixel light-emitting region, and the other end of each first diversion trench is connected to the accommodating region.
